(19) United States
(12) Patent Application Publication
(10) Pub. No.: US 2023/0204449 A1
(43) Pub. Date: Jun. 29, 2023

(54) APPARATUS AND METHOD FOR INSPECTING GAS LEAK

(71) Applicant: SEMES CO., LTD., Chungcheongnam-do (KR)

(72) Inventors: Mi Young JO, Gyeonggi-do (KR); Kyeong Hee KANG, Gyeonggi-do (KR); Young Ran KO, Daegu (KR); Da Som BAE, Seoul (KR)

(21) Appl. No.: 17/842,978

(22) Filed: Jun. 17, 2022

(30) Foreign Application Priority Data
Dec. 29, 2021 (KR) 10-2021-0191126

(51) Int. Cl. G01M 3/24

(52) U.S. Cl. CPC G01M 3/24

(57) ABSTRACT

Provided are an apparatus and method for inspecting a gas leak. The apparatus for inspecting a gas leak includes a chamber in which a substrate is accommodated; a gas supply unit configured to supply a gas for use in processing the substrate; an electrostatic chuck spaced apart from the substrate and having a gap space to which the gas is supplied; and a sensing unit configured to identify a location of gas leak in at least the electrostatic chuck

### CROSS-REFERENCE TO RELATED APPLICATION

This application claims priority from Korean Patent Application No. 10-2021-0191126 filed on Dec. 29, 2021 in the Korean Intellectual Property Office, and all the benefits accruing therefrom under 35 U.S.C. 119, the contents of which in its entirety are herein incorporated by reference.

### BACKGROUND

### 1. Technical Field

The present disclosure relates to an apparatus and method for inspecting a gas leak.

### 2. Description of the Related Art

It is known that a gas leak is largely caused due to etching and byproducts and deposition produced during a process. Existing technologies detect a helium (He) leak by creating a vacuum inside a chamber and then detecting the pressure change per hour. However, these technologies only can check the occurrence of a helium leak. If a gas leak is caused by etching, generally discard, or reuse after re-patterning is made. In the case of re-patterning, a ceramic portion has to be re-processed, which is time- and cost-consuming. Further, a gas leak is caused by byproducts and deposition, reuse is possible through cleaning, but the causes of existing gas leaks cannot be clearly identified by type and thus the disposal rate of an electrostatic chuck is high.

### PRIOR ART LITERATURE

[Patent Literature]

Korean Laid-open Patent Publication No. 10-2006-0007696

### SUMMARY

Aspects of the present disclosure provide an apparatus and method for inspecting a gas leak, which enable checking whether the cause of a gas leak in the process of processing a substrate is due to etching of an electrostatic chuck or byproducts and deposition by specifying a gas leak location.

Aspects of the present disclosure also provide an apparatus and method for inspecting a gas leak based on a means capable of effectively and clearly visualizing and confirming a gas leak in a chamber and the location thereof.

Aspects of the present disclosure also provide an apparatus and method for inspecting a gas leak, which are capable of promptly checking the cause of a gas leak based on secondary analysis after specifying a gas leak location.

Aspects of the present disclosure also provide an apparatus and method for inspecting a gas leak, which are capable of reducing the length of time required for deciding on re-patterning, cleaning process, and the like in a situation where an existing gas leak is not located.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, there is provided an apparatus for inspecting a gas leak including: a chamber in which a substrate is accommodated; a gas supply unit configured to supply a gas for use in processing the substrate; an electrostatic chuck spaced apart from the substrate and having a gap space to which the gas is supplied; and a sensing unit configured to identify a location of gas leak in at least the electrostatic chuck.

According to another aspect of the present disclosure, there is provided a method of inspecting a gas leak including: supplying, by a gas supply unit, a gas; attracting, by an electronic chuck provided in a chamber, a substrate held on an upper portion of the electronic chuck; supplying the gas to a gap space formed on the electrostatic chuck to be spaced apart from the substrate; and identifying, by a sensing unit, a location of a gas leak in at least the electrostatic chuck.

In addition, the method may further include determining, by a determination unit, occurrence of the gas leak in the electrostatic chuck by inspecting a target inspection location of the electrostatic chuck that corresponds to the location of the gas leak.

In addition, when external leakage of the gas occurs due to etching of the electrostatic chuck, the sensing unit may identify a location of the gas leak by sensing turbulence in the chamber generated corresponding to the external leakage of the gas.

Also, the sensing unit may be provided in the chamber and may detect the gas leaking from the electrostatic chuck using an ultrasonic method.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a block diagram illustrating a configuration of an apparatus for detecting a gas leak according to an embodiment of the present disclosure.

FIG. 2 is a diagram illustrating a configuration of FIG. 1.

FIG. 3 is a flowchart illustrating a method of detecting a gas leak according to an embodiment of the present disclosure.

FIGS. 4 to 6 are diagrams illustrating the method of detecting a gas leak of FIG. 3.

### DETAILED DESCRIPTION OF THE EMBODIMENTS

Hereinafter, preferred embodiments of the present disclosure will be described in detail with reference to the accompanying drawings. Advantages and features of the present disclosure and methods of accomplishing the same may be understood more readily by reference to the following detailed description of preferred embodiments and the accompanying drawings. The present disclosure may, however, be embodied in different forms and should not be construed as limited to the embodiments set forth herein. Rather, these embodiments are provided so that this disclosure will be thorough and complete, and will fully convey the scope of the invention to those skilled in the art. The same reference numbers indicate the same components throughout the specification.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

Although the terms first, second, etc. may be used herein to describe various elements, components, regions, layers, and/or sections, these elements, components, regions, layers, and/or sections should not be limited by these terms. These terms are used to distinguish one element, component, region, layer, and/or section from another element, component, region, layer, and/or section. Thus, a first element, component, region, layer, and/or section discussed below could be termed a second element, component, region, layer, and/or section without departing from the teachings of the present disclosure.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated components, steps, operations, and/or elements, but do not preclude the presence or addition of one or more other components, steps, operations, and/or elements.

Unless defined otherwise, all technical and scientific terms used herein have the same meaning as commonly understood by one of ordinary skill in the art to which this invention belongs. Further, unless defined otherwise, all terms defined in generally used dictionaries may not be overly interpreted.

Hereinafter, exemplary embodiments of the present disclosure will be described in detail with reference to the accompanying drawings. In the description with reference to the drawings, the same or corresponding elements are denoted by the same reference numerals, and a redundant description thereof will be omitted.

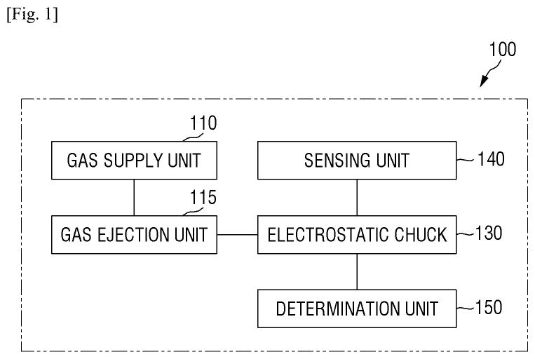

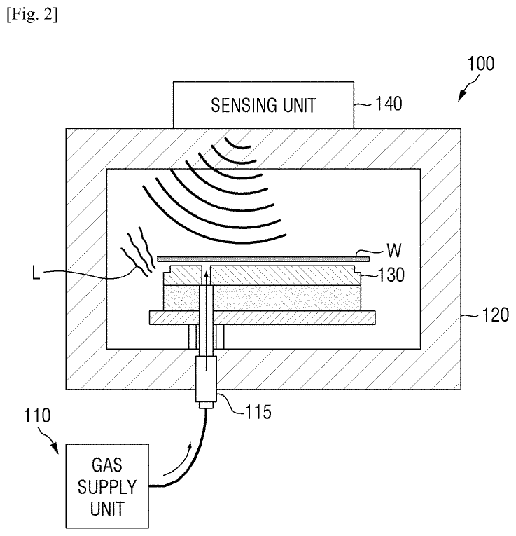

Referring to FIGS. 1 and 2, an apparatus 100 for detecting a gas leak according to an embodiment of the present disclosure includes a gas supply unit 110, a chamber 120, an electrostatic chuck 130, a sensing unit 140, and a determination unit 150. The chamber 120 accommodates a substrate W to process the substrate W. The gas supply unit 110 supplies a gas for processing the substrate W.

Here, the electrostatic chuck 130 forms a gap space S with the substrate W. The gas is supplied to the gap space S for use in processing the substrate W. Here, the gas may include a helium gas or the like.

The gas may be other processing gas for use in processing the substrate W, other than the helium gas. The sensing unit 140 identifies a location of a gas leak in at least the electrostatic chuck 130.

Although a single sensing unit 140 is provided and located at an upper portion of the chamber 120 in the drawings, this is merely exemplary. When a single sensing unit 140 is provided, the sensing unit 140 may be provided vertically on at least one of both sides of the chamber 120 or may be provided horizontally on an upper or lower side of the chamber 120.

Further, when the sensing unit 140 is provided in plurality, the sensing units 140 may be provided vertically on at least one of both sides of the chamber 120, or may be arranged horizontally on an outer upper or lower side of the chamber 120.

The determination unit 150 inspects an inspection target location of the electrostatic chuck that corresponds to the location of the gas leak. By doing so, the determination unit 150 determines the occurrence of the gas leak in the electrostatic chuck.

When the external leakage of the gas occurs due to etching of the electrostatic chuck 130, the sensing unit 140 locates the gas leak by sensing turbulence L in the chamber 120 generated corresponding to the external leakage of the gas.

The sensing unit 140 is provided in the chamber 120 to detect the gas leaking from the electrostatic chuck 130 using an ultrasonic method.

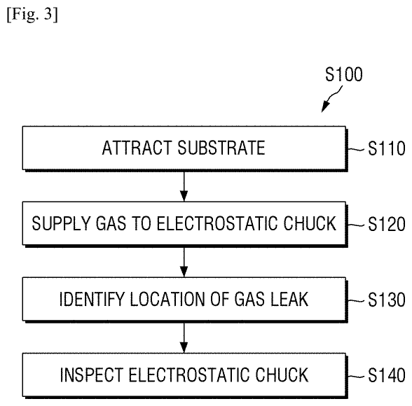

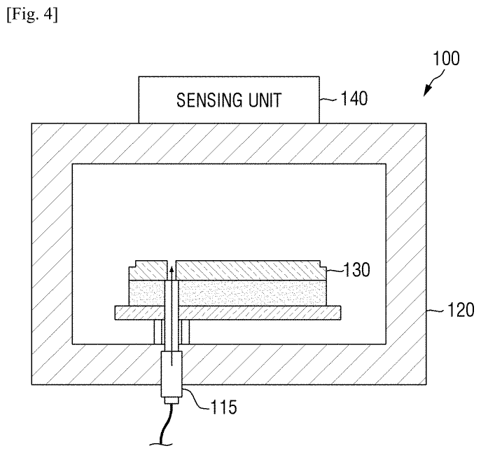

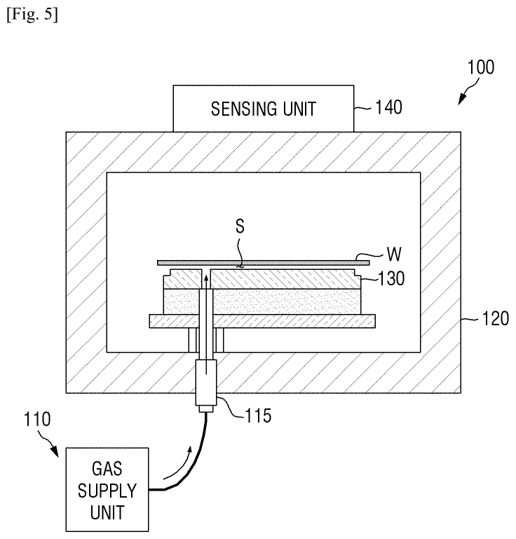

Referring to FIGS. 3 to 6, in a method S100 of inspecting a gas leak according to an embodiment of the present invention, the gas supply unit 110 supplies a gas. In addition, a substrate W in the chamber 120 is located at an upper portion of the electrostatic chuck 130. Here, the substrate W is attracted and fixed on the electrostatic chuck 130. (see S110 and S120 in FIG. 3 and FIGS. 4 and 5)

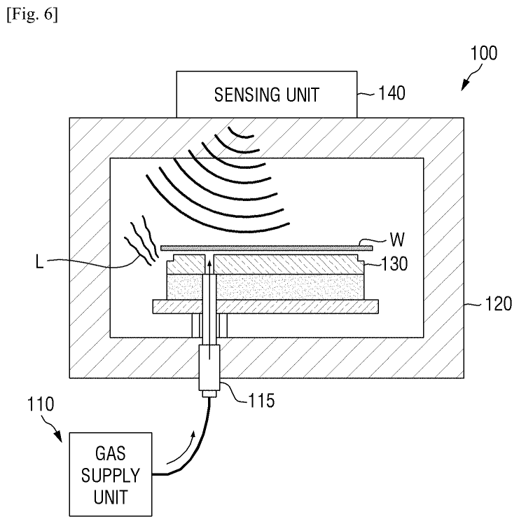

The gas is supplied to a gap space S formed on the electrostatic chuck 130 to be spaced apart from the substrate W. The sensing unit 140 identifies a location of a gas leak in at least the electrostatic chuck 130. (see S130 in FIG. 3 and FIG. 6)

Further, the determination unit 150 inspects a target inspection location of the electrostatic chuck that corresponds to the location of the gas leak. The determination unit 150 determines the occurrence of the gas leak in the electrostatic chuck. The determination unit 150 includes a measurement unit (not shown) that uses a three-dimensional measurement method (S140 in FIG. 3).

When the external leakage of the gas occurs due to etching of the electrostatic chuck 130, turbulence L is generated in the chamber 120 corresponding to the external leakage of the gas. The sensing unit 140 identify the location of the gas leak by sensing the turbulence.

Here, the sensing unit 140 is provided in the chamber 120 and detects the gas leaking from the electrostatic chuck 130 using an ultrasonic method. That is, the ultrasonic method is applicable as a means for sensing the turbulence.

According to the apparatus and method for inspecting a gas leak, one or more of the following effects may be achieved.

The present disclosure allows for gas leak inspection that enables checking whether the cause of a gas leak is due to etching of an electrostatic chuck or byproducts and deposition.

In addition, gas leak inspection may be performed based on a means capable of efficiently and clearly visualizing and checking a gas leak in a chamber and the location thereof.

Additionally, gas leak inspection may be performed which can promptly identify the cause of a gas leak based on secondary analysis after specifying the gas leak location.

Further, gas leak inspection may be performed which can reduce the length of time required for deciding on re-patterning, cleaning process, and the like in a situation where an existing gas leak is not located.

While various embodiments have been described, those skilled in the art will appreciate that many variations and modifications can be made to the preferred embodiments without substantially departing from the principles of the present disclosure. Therefore, the disclosed preferred embodiments of the invention are used in a generic and descriptive sense only and not for purposes of limitation.

What is claimed:

1. A method of inspecting a gas leak, comprising:
placing a substrate, which is in a chamber, on an upper portion of an electrostatic chuck;
supplying a gas to a gap space formed on the electrostatic chuck to be spaced apart from the substrate; and
identifying, by a sensing unit, a location of a gas leak in at least the electrostatic chuck.

2. The method of claim 1, further comprising determining, by a determination unit, occurrence of the gas leak in the electrostatic chuck by inspecting a target inspection location of the electrostatic chuck that corresponds to the location of the gas leak.

3. The method of claim 2, wherein, when external leakage of the gas occurs due to etching of the electrostatic chuck, the sensing unit is configured to identify a location of the gas leak by sensing turbulence in the chamber generated corresponding to the external leakage of the gas.

4. The method of claim 2, wherein the sensing unit is provided in the chamber and is configured to detect the gas leaking from the electrostatic chuck using an ultrasonic method.

5. A method of inspecting a gas leak, comprising:
placing a substrate, which is in a chamber, on an upper portion of an electrostatic chuck;
supplying a gas to a gap space formed on the electrostatic chuck to be spaced apart from the substrate;
identifying, by a sensing unit, a location of a gas leak in at least the electrostatic chuck; and
determining, by a determination unit, occurrence of the gas leak in the electrostatic chuck by inspecting a target inspection location of the electrostatic chuck that corresponds to the location of the gas leak,
wherein, when external leakage of the gas occurs due to etching of the electrostatic chuck, the sensing unit is configured to identify a location of the gas leak by sensing turbulence in the chamber generated corresponding to the external leakage of the gas, wherein the sensing unit is provided in the chamber and is configured to detect the gas leaking from the electrostatic chuck using an ultrasonic method.

6. An apparatus for inspecting a gas leak, comprising:
a chamber in which a substrate is accommodated;
a gas supply unit configured to supply a gas for use in processing the substrate;
an electrostatic chuck spaced apart from the substrate and having a gap space to which the gas is supplied; and
a sensing unit configured to identify a location of gas leak in at least the electrostatic chuck.

7. The apparatus of claim 6, further comprising a determination unit configured to determine occurrence of the gas leak in the electrostatic chuck by inspecting a target inspection location of the electrostatic chuck that corresponds to the location of the gas leak.

8. The apparatus of claim 7, wherein, when external leakage of the gas occurs due to etching of the electrostatic chuck, the sensing unit is configured to identify a location of the gas leak by sensing turbulence in the chamber generated corresponding to the external leakage of the gas.

9. The apparatus of claim 7, wherein the sensing unit is provided in the chamber and is configured to detect the gas leaking from the electrostatic chuck using an ultrasonic method

10. An apparatus for inspecting a gas leak, comprising:
a chamber in which a substrate is accommodated;
a gas supply unit configured to supply a gas for use in processing the substrate;
an electrostatic chuck spaced apart from the substrate and having a gap space to which the gas is supplied; and
a sensing unit configured to identify a location of gas leak in at least the electrostatic chuck, wherein, when external leakage of the gas occurs due to etching of the electrostatic chuck, the sensing unit is configured to identify a location of the gas leak by sensing turbulence in the chamber generated corresponding to the external leakage of the gas, wherein the sensing unit is provided in the chamber and is configured to detect the gas leaking from the electrostatic chuck using an ultrasonic method.
